(19) United States
(12) Patent Application Publication
(10) Pub. No.: US 2025/0277848 A1
(43) Pub. Date: Sep. 4, 2025

(54) PROBE HEAD AND PROBE CARD FOR TESTING HIGH VOLTAGE SEMICONDUCTOR COMPONENTS AND SYSTEMS INCLUDING AND METHODS OF USING THE SAME

(71) Applicant: Cohu GmbH, Kolbermoor (DE)

(72) Inventors: Stefan Engelbrecht, Bruckmühl (DE); Christoph Mederer, Bad Feilnbach (DE); Mathias Westenhuber, Samerberg (DE); Markus Wagner, Kolbermoor (DE)

(21) Appl. No.: 19/066,969

(22) Filed: Feb. 28, 2025

(30) Foreign Application Priority Data
Feb. 29, 2024 (EP) 24160677.1

(51) Int. Cl. G01R 31/28

(52) U.S. Cl. CPC G01R 31/2886

(57) ABSTRACT

A probe head may include a plurality of test sites, each configured to test a different one of the electronic components. A probe head may include a plurality of groups of contact elements, each associated with a different test site and configured to contact a respective electronic component to be tested in the different test site. A probe head may include a plurality of gas supply channels, each passing through a respective test site and configured to supply pressurized gas to a respective group of contact elements associated with the respective test site.

### CROSS-REFERENCE TO RELATED APPLICATIONS

This application claims foreign priority to European Patent Application No. EP 24160677.1, filed Feb. 29, 2024, the content of which is incorporated by reference herein in its entirety.

### TECHNICAL FIELD

The disclosed technology generally relates to probers. Probers can be used to test semiconductor components (also referred to as devices under test or DUTs), integrated on a wafer. The disclosed technology also includes probe heads and probe cards of a prober and methods using the same.

### BACKGROUND

In general, testing of semiconductor components may be done when the semiconductor components are already separated or when the semiconductor components are still integrated on the wafer. Testing of separated or singulated semiconductor components can be more expensive, since further steps, such as dicing and packaging may be performed prior to testing, which can delay the testing while adding cost to potentially failed components. For example, for semiconductor components, such as electronic components, that fail a test, the step of packaging may be useless. As a consequence, there is an ever-increasing demand to test the electronic components on a wafer. This also applies to high voltage components, sometimes also referred to as “high power components,” and to parallel testing. High voltage components are often tested under pressurized gas or air, according to Paschen's Law, so that arcing may be avoided. However, testing equipment is often rectangular and form rectangular pressurized chambers which can prevent parallel testing for electronic components located at the edge of a circular wafer.

### SUMMARY

In view of the above, there is a need for a prober test, in particular as a parallel test, for high voltage electronic components that reduces duplicate testing of the electronic components and/or reduces untested electronic components on a wafer.

Disclosed herein is a probe head for parallel testing a plurality of electronic components on a wafer, according to various embodiments. Further, methods of parallel testing electronic components using the probe head are disclosed.

According to an embodiment of the invention, a probe head for parallel testing a plurality of electronic components on a wafer, in particular for parallel testing high voltage semiconductor components, comprises: an arrangement of a plurality of test sites, each test site adapted to test a different electronic component, a plurality of groups of contact elements, each group of contact elements (of the plurality of group of contact elements) assigned to a different one of the test sites and adapted to contact to the respective electronic component, and a plurality of gas supply channels, each gas supply channel passing through a different test site of the plurality of test sites and supplying separately pressurized gas to the assigned group of contact elements.

According to an embodiment of the invention, a method of parallel testing a plurality of electronic components on a wafer, in particular for parallel testing high voltage semiconductor components, comprises: providing an arrangement of a plurality of test sites wherein each test site is adapted to test a different electronic component, providing a plurality of groups of contact elements, each group of contact elements (of the plurality of group of contact elements) assigned to a different one of the test sites and adapted to contact to the respective electronic component, providing, in a probe head, a plurality of gas supply channels, each gas supply channel passing through a different test site of the plurality of test sites, parallel testing the plurality of electronic components by contacting the assigned group of contact elements to the plurality of electronic components on the wafer, and supplying separately pressurized gas to the assigned group of contact elements by the gas supply channels.

The expression “probe head” may denote a core component of a probe card. The probe head can be a part of the probe card which includes probes, or contact elements for contacting to an electronic component (also referred to herein as a “device under test” or a “DUT”), or a plurality of DUTs. The probe head can include and define the number of input and output connections (“I/Os”), proportional to the number of DUTs which may simultaneously be tested by the probe head. The expression “test site” may denote a functional part of the probe head. One test site may comprise the number of I/Os sufficient to test one DUT. The expression “contact element” may denote the part of a test site for functionally forming one I/O. E.g., the contact element may be formed as a wire probe, so-called “cantilever contact spring”, or as a so-called “pogo pin”. The contact element enables to contact to one contact portion of the DUT and the contact element transmits electrical signals to a board which in turn transmits the electrical signals to a computer for further analysis. The expression “group of contact elements” may refer to the number of contact elements, or number of functional I/Os, respectively, used to test one DUT. The expression “gas supply channel” may denote a part of the test site, and in particular, may denote a path to guide gas or air inside the test site and towards the contact elements. The expression “pressurized gas” may denote a gas having a pressure value which reduces a risk of arcing from one contact to a neighbouring contact element, to a neighbouring test site, or to a neighbouring DUT, according to Paschen's Law. The expression “supplying separately pressurized gas to an assigned group of contact elements by the gas supply channels” may denote that gas having a pressure value for reducing arcing may be guided inside one test site to its assigned group of contact elements.

According to embodiments of this disclosure, a pressure decay caused from a specific test site can be limited when the specific test site is not located above a wafer. As a basis for this, each of a plurality of test sites may comprise a specific flow resistance, providing sufficiently pressurized gas for each of the test sites used to test DUTs on a wafer. Advantageously, the flow resistance of for each of the gas supply channels may be shaped, which may provide pressurized gas through individual gas supply channel. In other words: A test head can include a plurality of test sites. One test site can comprise one (assigned) group of contact elements for contacting to one DUT or electronic component. One test site can comprise (at least) one individual gas supply channel for supplying pressurized gas to the assigned group of contact elements. That is, for every DUT and for each group of contact elements there can be (at least) one path or gas supply channel for providing the pressurized gas. Having an individual supply of providing pressurized gas inside (each) one of the test sites may be a basis for limiting pressure loss or pressure decay, when a test site is not positioned above the wafer or an electronic component. Limiting pressure loss may be achieved by adjusting a flow resistance inside or towards each of the plurality (of at least two) gas supply channels. Adjusting the flow resistance for a gas supply channel may be achieved upstream in the gas supply by a static initial design, by a design allowing for individual and/or manual adjustment of a diameter of a narrow passage, by adjusting an electronically controllable throttle valve, or by any combination thereof.

According to an exemplary embodiment of the probe head, the supply of separately pressurized gas through the gas supply channels is adaptable by a mechanical adjustment of a flow resistance for the plurality of the gas supply channels.

A mechanical and manual adjustment of the flow resistance may include any design applied to an upstream path which allows for the flow resistance to be initially set or limited and/or later set or limited to a certain value.

According to an exemplary embodiment of the probe head, a flow resistance for multiple of the gas supply channels is individually adjustable for each of the multiple gas supply channels.

In one embodiment, the flow resistance of multiple of the gas supply channels may be changed individually to adapt the flow resistance for each of this multiple gas supply channels. Initially setting the flow resistance to a specific value and mechanically and/or manually adjusting the flow resistance in a further action may be seen independently, and hence may applied simultaneously or separately. I.e., an initial design and a later adjustment do not exclude each other for neither the probe head nor for the test site.

According to an exemplary embodiment, the probe head further comprises a plurality of electronically controllable throttle valves. Each one of the electronically controllable throttle valves can be assigned to a different one of the gas supply channels. Further, a flow resistance through each of the gas supply channels can be electronically controlled by using the respective electronically controlled throttle valve.

Using electronically controllable throttle valves may be a further measure to adjust the flow resistance. Different measures may be applied individually or separately for one or each of the plurality of test sites. For example, an initial design, mechanical or manual adjustment, and electronically controlled throttle valves may be provided mutually or separately for an arbitrary sub-group of the gas supply channels.

According to an exemplary embodiment of the probe head, the flow resistance through each of the gas supply channels is increased as to switch off the flow completely by an assigned electronically controllable throttle valve.

One measure to limit gas pressure decay is to completely close a gas supply channel when the respective test site is located beside the wafer. This may be advantageous for reducing noise which may be caused by escaping air from the specific test site being which is not located above the wafer.

According to an exemplary embodiment, the probe head includes a gas supply. The gas supply can provide pressurized gas for each of the plurality of gas supply channels.

In some instances, one device and one supply line feeds pressurized gas of a specific pressure value towards and into the probe head. Downstream of the gas supply, the flow resistance for a gas supply channel may be set to a value so that a pressure decay caused by a test site which is not located above the wafer is limited.

According to an exemplary embodiment of the probe head, the separately pressurized gas can be set to a pressure value that can prevent arcing between the contact elements within each group of contact elements, between two neighbouring test sites, or between neighbouring DUTs, according to Paschen's Law.

The pressure value of the pressurized gas used in the probe head may be sufficient, according to Paschen's Law, to allow for the DUTs to be tested and avoid harm by arcing which may take place between neighbouring contact elements within one group of contact elements, between two neighbouring test sites, or between neighbouring DUTs.

According to an exemplary embodiment of the probe head, arcing between a first number of contact elements, adapted to contact to the wafer, can be suppressed or prevented according to Paschen's Law, in that a suitable gas pressure according to Paschen's Law is fulfilled for the first number of contact elements, by, in combination, providing separately pressurized gas with a specific pressure value for each of the contact sites and setting a specific value of the flow resistance through gas supply channels for a respective second number of contact elements not in contact with the wafer. In particular, the first number of contact elements does not overlap with the second number of contact element, respectively. In particular, the first number of contact elements may comprise contact elements within one group of contact elements, contact elements of two neighbouring test sites, or contact elements contacting to different or neighbouring DUTs.

The first number of contact elements may refer to a first subset of the plurality of groups of contact elements. The first number of contact elements may contact to DUTs of the wafer and may be provided with pressurized gas according to Paschen's Law. The second number of contact elements may refer to a second subset of the plurality of groups of contact elements which are located beside the wafer. There may be a pressure decay for the first subset caused by the second subset. However, depending on the distance of the contact elements, the provided gas pressure, the number of contact elements in the second subset, respectively, the pressure applied to the first number of contact elements may be sufficiently high enough to fulfil Paschen's Law for the contacting first number of contact elements.

According to an exemplary embodiment of the probe head, the pressurized gas is pressurized air.

According to an exemplary embodiment of the probe head, the arrangement of the test sites provides a plurality of test gaps between the test sites in that the test sites are adapted to test every other (or less than every other) of the electronic components in one and/or another direction of a main plane of the wafer.

There may be test gaps between the test sites in one or another direction, so that there are DUTs in between neighbouring test sites which are not tested. For example, a grid of test sites may be less dense than a grid of DUTs. This may be advantageous in that there may be more space to integrate the gas supply channels into the test site or to integrate a gas distribution splitting the gas supply into the separate gas supply channels within the test head or upstream of the test head.

According to an exemplary embodiment, the probe head further comprises a bottom surface, the bottom surface comprising a main portion and a plurality of elevated portions, wherein each one of the elevated portions surrounds a different one of the groups of contact elements. The elevated portions are raised relative to the main portion.

The expression “bottom surface” or “bottom surface of the probe head” may denote the surface facing towards the wafer and extending in the same main plane as the main plane of the wafer. The expression that “elevated portions are raised relative to the main portion” of the bottom surface may denote that the complete bottom surface comprises a smaller area, namely “the elevated portions” and a larger area, namely the “main surface”. The elevated portions may be elevated or higher compared to the main surface. The area of the elevated portions may be flat, so that any part of the elevated portions may have the same distance towards a wafer and may have the same height relative to the main surface of the bottom surface of the probe card. In this sense, the bottom surface of the probe card may have two parallel flat surfaces wherein the area of the elevated portions may be seen as a heightened contour on the main portion. Each single elevated portion of the elevated portions may surround exactly one group of contact elements of exactly one test site. There may be a one-to-one relationship between the raised surfaces and the test site, or the contact elements, respectively.

The elevated portions or raised surfaces can allow the contact elements to be separated in relation to the pressure, which may be supplied by a gas supply towards the test sites. That is, the pressure inside each of the test sites and around the contact elements may be higher and may prevent sparkover which could otherwise damage the DUTs and/or the test equipment. In addition, it may be easier to regulate and balance the pressure within the elevated portions since, if e.g. the elevated portions are chosen in a ring-like form. The ring-like form may have a circular, a rectangular or a quadratic shape or outline. In this case, there can be a defined flow resistance given, mostly dependent on the width of the ring-like elevated portions. However, any form or contour of the elevated portions may be suitable if the pressure around the contact elements is raised during a test of the DUTs. A distance from the elevated portions or from the bottom surface, if being completely flat, towards the wafer may be 20-200 μm. This distance towards the wafer may also be “micro gap”.

According to an exemplary embodiment, a probe card comprises a probe head according to any of the previously mentioned embodiments, and further comprises: a board with a plurality of through holes and a gas distribution unit The gas distribution unit can separate the gas supply into different gas supply branches each entering a different one of the plurality of through holes. Each one of the plurality of through holes of the board can be arranged between the gas distribution unit and the probe head can feed a different one of the gas supply channels, each with separately pressurized gas.

In various embodiments, the throttle valves may be arranged inside the probe head or may be arranged inside the gas distribution unit.

According to an exemplary embodiment, a method of supplying separately pressurized gas through the gas supply channels is described, the method comprising adapting a flow resistance for the plurality of the gas supply channels by a mechanical adjustment.

In various embodiments, adapting the flow resistance may be done by design before testing. In these embodiments, the first gas supply channels may be designed ready to use and an adaption of the flow resistance may happen automatically (e.g., caused by turbulent flow through the gas supply channels).

According to an exemplary embodiment, the method comprises adjusting a flow resistance for multiple of the gas supply channels individually for each of the multiple gas supply channels.

In various embodiments, adapting the flow resistance may be done before testing, when done manually.

According to an exemplary embodiment, the method comprises providing a plurality of electronically controllable throttle valves, each one of the electronically controllable throttle valves assigned to a different one of the gas supply channels. The method further comprises electronically controlling a flow resistance through each of the gas supply channels by using the respective electronically controlled throttle valve.

According to an exemplary embodiment, the method comprises increasing a flow resistance through each of the gas supply channels as to switch off the flow completely by the assigned electronically controllable throttle valve.

According to an exemplary embodiment, the method comprises providing a gas supply and providing pressurized gas for each of the plurality of gas supply channels by the gas supply.

According to an exemplary embodiment, the method comprises setting the separately pressurized gas to a pressure value to prevent arcing between the contact elements within each group of contact elements, between two neighbouring test sites, or between neighbouring DUTs, according to Paschen's Law.

According to an exemplary embodiment, the method comprises preventing arcing between a first number of contact elements according to Paschen's Law, the first number of contact elements contacting to the wafer, by providing a suitable gas pressure according to Paschen's Law for the first number of contact elements, providing separately pressurized gas with a specific pressure value to the first number of contact elements, and setting a specific value of the flow resistance through gas supply channels for a respective second number of contact elements, the second number of contact elements not in contact to the wafer.

According to an exemplary embodiment, the method comprises providing pressurized air as the pressurized gas.

According to an exemplary embodiment, the method comprises providing a plurality of test gaps between the test sites and testing every other, or less than every other, of the electronic components in one and/or the other direction of a main plane of the wafer.

According to an exemplary embodiment, the method comprises providing a probe card and further providing a board with a plurality of through holes, and a gas distribution unit. The gas distribution unit can separate the gas supply into different gas supply branches, each entering a different one of the plurality of through holes. Each one of the plurality of through holes of the board can be arranged between the gas distribution unit and the probe head. In the exemplary embodiment, the method further comprises feeding a different one of the gas supply channels with separately pressurized gas by a respective through hole.

### BRIEF DESCRIPTION OF THE DRAWINGS

The aspects defined above, and further aspects of the present invention, are apparent from the examples of embodiment to be described hereinafter and are explained with reference to the examples of embodiments. The invention will be described in more detail hereinafter with reference to examples of embodiments but to which the invention is not limited.

FIG. 1A shows a probe card in perspective view from above, according to an embodiment of the present invention.

FIG. 1B shows a cross-sectional view of the probe card indicated with FIG. 1A.

FIG. 1C shows the probe card in a perspective view from below, according to an embodiment of the invention.

FIG. 2A shows a cross-sectional view of a detail of the probe card illustrated in FIG. 1B.

FIG. 2B shows a cross-sectional view of a detail of the probe card illustrated in FIG. 2A.

FIG. 3A shows a schematic illustration of pressurized gas distribution of the probe card while testing semiconductor components of a wafer, according to an embodiment of the invention.

FIG. 3B shows a schematic illustration of the probe card when testing semiconductor components of a wafer, when the probe card is partially located next to the wafer.

FIG. 4A shows the gas distribution unit according to an embodiment of the invention.

FIG. 4B shows a bar chart of a flow rate decay according to an embodiment of the invention.

FIG. 4C shows a bar chart of a pressure decay according to an embodiment of the invention.

FIG. 5 shows a semiconductor test equipment in a perspective view, according to an embodiment of the invention.

### DETAILED DESCRIPTION

The illustrations in the drawings are schematic. It is noted that in different figures similar or identical elements are provided with the same reference signs.

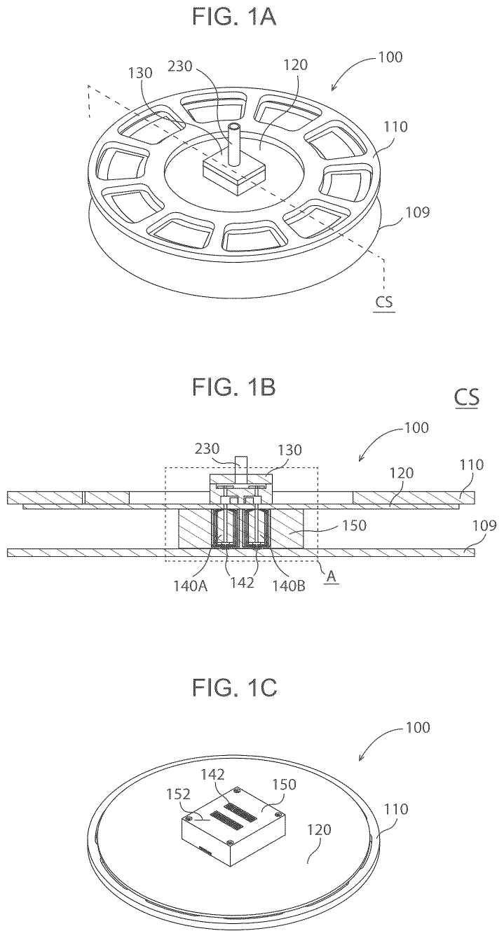

FIG. 1A shows a top view of a probe card 100. In this perspective view from above four parts of the probe card 100 are visible: The probe card comprises a stiffener 110 for supporting a board (such as a printed circuit board or “PCB”) 120. Central to the board 120 and the stiffener 110, the probe card 100 comprises a gas distribution unit 130 and on top of it a gas supply 230, for providing pressurized gas to the gas distribution unit 130. Below the probe card 100 and not part of the probe card 100 is a wafer 109 is shown which may comprise electronic components to be tested (also referred to a devices under test or “DUTs” or semiconductor components) facing towards a bottom surface of the probe card 100.

As described herein, a wafer refers to a substrate including, without limitation, a suitable semiconductor material, including Group IV semiconductors such as silicon (Si), germanium (Ge) and silicon carbide (SiC), or compound semiconductors formed of elements of Groups III and V or elements of Groups II and VI. Without limitation, some high voltage semiconductors can be Si-, GaN- or SiC-based semiconductor devices. In various embodiments disclosed herein, the substrate can include integrated circuit (IC) devices fabricated thereon.

As described herein, high voltage semiconductor devices refer to semiconductor devices configured for operation at relatively high voltages, e.g., 5-50V, 50-100V, 100-200V, 200-300V, 300 400V or a value in a range defined by any of these values or higher. Without limitation, high voltage semiconductor devices can include field effect devices such as, e.g., complementary metal oxide semiconductor (CMOS) devices and double diffused MOS (DMOS) devices. CMOS devices can provide high speed and high density digital functionalities, and DMOS devices can support high power and high-voltage operations. Without limitation, high voltage semiconductor devices can also include bipolar devices such as, e.g., bipolar transistors, which can provide precise and high speed analog functionalities. Without limitation, high voltage semiconductor devices find many applications, e.g., power transmission, motor control, and power supplies, to name a few.

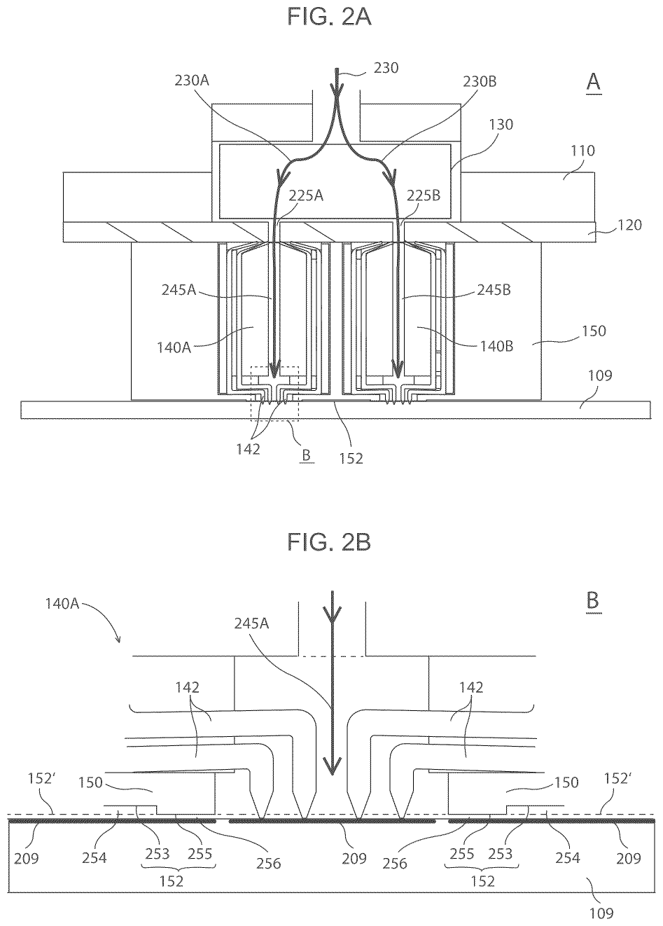

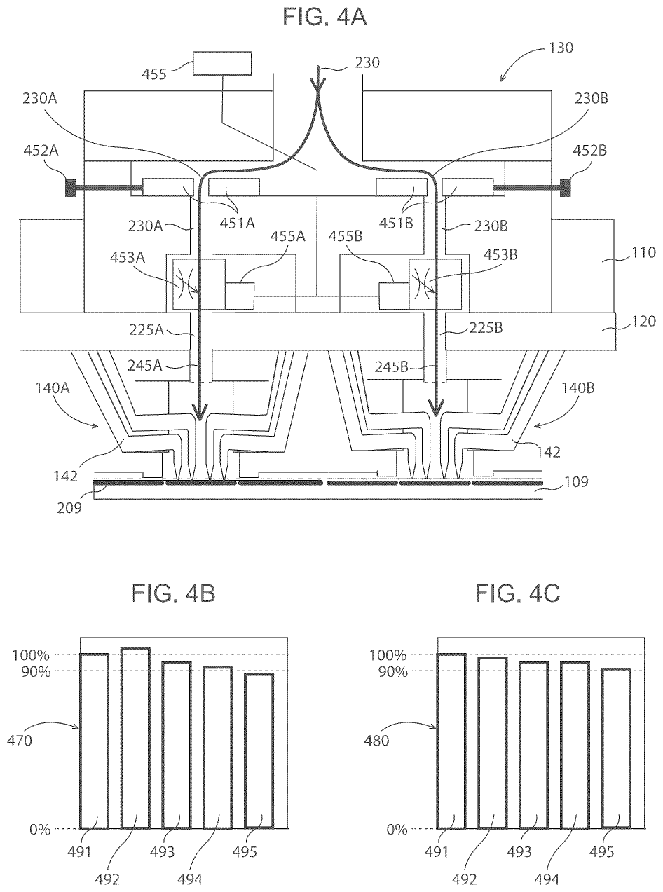

FIG. 1B shows a cross-sectional view of the probe card 100 indicated with FIG. 1A. In addition to FIG. 1A, the cross section (CS as indicated in FIG. 1A) in FIG. 1B shows two test sites 140A, 140B each comprising a plurality of contact elements 142, for contacting to DUTs of the wafer 109. The gas distribution unit 130 and the test sites 140 are separated by the board 120. Further, the arrangement of the test sites 140A, 140B is also held and fixed by a probe head 150 at a centre of the probe board 120 (and the stiffener 110). The probe head 150 comprises the test sites 140A, 140B extending between the board 120 and the wafer 109. A dashed line A indicates a detail of the probe card 100 which is described in more detail with FIG. 2A and partially with FIG. 4.

FIG. 1C shows a bottom view of the probe card 100. In this perspective view of a bottom side, three functional parts of the probe card 100 are visible: The board 120 covers nearly the entire stiffener 110. Again, central to the board 120 (and the stiffener 110) there is the probe head 150 having a specific bottom surface 152. The plurality of contact elements 142 form the test sites 140A, 140B (see also FIG. 1B), and not depicted in FIG. 1C. However, the bottom surface 152 of the probe head 150 encloses the test sites 140 and the contact elements 142.

FIG. 2A shows detail A of the probe card as indicated with FIG. 1B. From top to bottom, FIG. 2A shows: The gas supply 230 feeds pressurized gas into the gas distribution unit 130 in which the pressurized gas is split into two paths of which the first branch 230A is led into the (left and) first test site 140A and the second branch 230B of pressurized gas is led into the (right and) second test site 140B. The process of properly splitting the pressurized gas into two branches by the gas distribution unit 130 will be described with FIG. 4. The first (and) left branch 230A of pressurized gas may pass a first (and left) through hole 225A of the board 120, and may flow into a central (and left) first gas supply channel 245A. From there the pressurized gas flows towards the wafer 109. With FIG. 2B the design of the test site 140A, 140B and the flow of the pressurized gas in a proximity of the wafer 109 will be described in more detail with detail B, as indicated with a dashed line B in FIG. 2A. In a similar way, the second (and right) branch 230B of pressurized gas may pass a second (and right) through hole 225B of the board 120, and may flow into a central (and right) second gas supply channel 245B before entering the right test site 140B and from there flowing to the wafer 109. The first test site 140A and the second test site 140B may be fixedly held inside probe head 150 and may be a part of the probe head 150.

In addition to FIG. 2A, in FIG. 2B a plurality of electronic components 209 of the wafer 109 are shown. The contact elements 142 (in this case formed as cantilever contact springs though other contact elements may be used without departing from this disclosure) of the test site 140A contact to an electronic component 209 being positioned directly central to and below the test site 140A. The bottom surface 152 of the probe head 150 extends in a rectangular shape as an elevated portion 255 around the central electronic component 209. While the elevated portion 255 faces towards the wafer 109 or electronic components 209, respectively, the elevated portion 255 forms a narrow venting slot 256 with the wafer 109 without touching the surface of the wafer 109, or without touching the electronic components 209, respectively. The main portion 253 of the bottom surface 152 of the probe head 150 is set back in comparison to the ring-like raised or elevated portion 255 of the bottom surface 152 of the probe head 150. As a consequence, the pressurized gas flows from the gas supply channel 245A of the test site 140A towards the central electronic component 209. From there, the pressurized gas is urged to pass the narrow venting slot 256 formed by the ring-like raised or elevated portion 255 and flows further outwards to the main portion 253 forming a wider venting slot 254 with the wafer 109. Hence, when the pressurized gas supplied by the gas supply 230 flows towards the elevated portion 255, the narrow venting slot 256 of the elevated portion 255 causes downstream a higher flow resistance on the gas flow 230 and thus there is a higher gas pressure around the group of contact elements 142. In addition, the ring-like elevated portion 255 directly surrounding the central electronic component 209 may have a width so that the ring-like elevated portion 255 may face towards other electronic components 209 which are adjacent to the central electronic component 209.

As an alternative, the probe head 150 may comprise a uniformly even bottom surface 152′ as indicated with a dashed line. In this embodiment the flow resistance distributes evenly over a complete area of the bottom surface 152′ of the probe head 150.

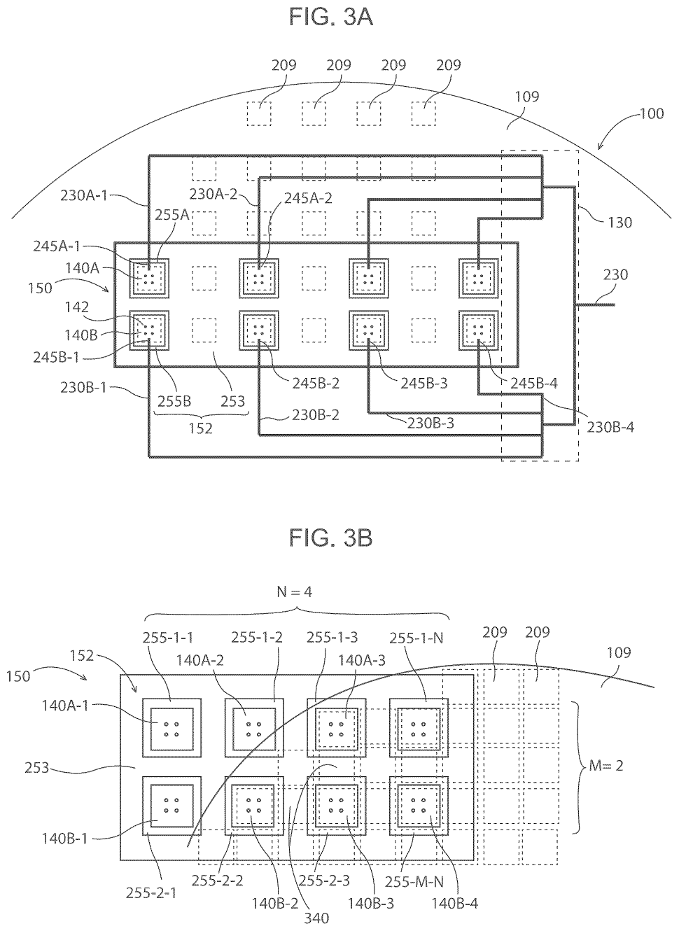

FIG. 3A shows a schematic illustration of pressurized gas distribution of the probe card 100 when testing semiconductor components 209 of a wafer 109. The pressurized gas is supplied by the gas supply 230 and distributed by the gas distribution unit 130 (depicted schematically) to an arrangement or matrix of contacted electronic components 209 by a plurality of branches 230A-1, 230B-1, 230A-2, 230B-2, 230B-3, 230B-4. Each electronic component 209 being contacted is supplied by one of the plurality of branches 230A-1, 230B-1, 230A-2, 230B-2, 230B-3, 230B-4. The branches 230A-1, 230B-1, 230A-2, 230B-2, 230B-3, 230B-4 terminate towards the gas supply channels 245A-1, 245B-1, 245A-2, 245B-2, 245B-3, 245B-4. This means, that the gas distribution unit 130 distributes the pressurized gas into a plurality of branches 230A-1, 230B-1, 230A-2, 230B-2, 230B-3, 230B-4 which then end towards a plurality of gas supply channels 245A-1, 245B-1, 245A-2, 245B-2, 245B-3, 245B-4 supplying separately pressurized gas to a plurality of electronic components 209, respectively. Each test site 140A, 140B, etc. may comprise a group of contact elements 142 and may contact to a different one of the electronic components 209.

Moreover, in this embodiment, each contacted electronic component 209 is surrounded by one ring-like elevated portion 255A, 255B, etc. The pressure of the pressurized gas builds up for each of the contacted electronic components 209. The built-up pressure may be higher than the ambient pressure by a suitable amount such that arcing during testing is substantially suppressed or avoided. For example, the pressure may be higher than an atmospheric pressure by, e.g., at least 1%, 2%, 5%, 10%, 20%, 50% or any value in a range defined by any of these values. The complete bottom surface 152 of the probe card (or the probe head 150, respectively,) may be formed by the plurality of ring-like, raised or elevated portions 255A, 255B, etc. and the main portion 253 which may be set back relative to the ring-like elevated portions 255A, 255B, etc.

FIG. 3B shows a schematic illustration of the bottom surface 152 of the probe card 100 when electronic components 209 of a wafer 109 are tested, and when the probe card 100 is partially located next to the wafer 109. As illustrated, wafers 109 can be circular with electronic components 209 arranged in regular lines and rows on the wafer 109. The test sites 140 and their contact elements 142 are illustrated as arranged in a M×N matrix of M lines and N rows for testing the electronic components 209. However, the test sites 140 may be arranged in any grid-like form or any grid-like manner, where each one of the test sites 140 faces one different electronic component 209. FIG. 3A shows the bottom surface 152 of the probe head 150 wherein each test site 140A-1, 140B-1, etc. and the respective contact elements 142 are surrounded by one ring-like elevated portion 255-1-1, 255-2-1, 255-1-2, . . . , 255-M-N, so that one ring-like elevated portion 255 corresponds to one electronic component 209.

In addition, according to the embodiment shown in FIG. 3B, the test sites 140 may be arranged so that one electronic component 209 is skipped in both directions of the main plain of the wafer, so that only every other electronic component 209 is tested in one specific row of electronic components 209. This may allow for the ring-like elevated portions 255 to overlap with electronic components 209 which are not tested. The omitted electronic components 209 which are not tested may be called “test gaps 340” on the test head 150 side.

In addition, the probe card 100 may reach a rounded end of the wafer 109, so that some of the test sites 140 (and in this case the test sites 140-1, 140-2, 140-3) are not located above the wafer 109. This means that these test sites 140-1, 140-2, 140-3 not only do not test electronic components 209 but also will lose the pressurized gas according to the then “open” branches 230A, 230B, 230C of pressurized gas.

FIG. 4A refers back to FIG. 2A and that the pressurized gas may be appropriately split into different branches, e.g. the first branch 230A and the second branch 230B which then feed the first gas supply channel 245A and the second gas supply channel 245B (see also FIG. 2A) through the first through hole 225A and the second through hole 225B of the board (PCB) 120, respectively. The gas distribution unit 130 may divide or split the pressurized gas from the gas supply 230 as follows: The gas distribution unit 130 may comprise a first distribution branch 230A, and a second distribution branch 230B both being connected to the gas supply 230 on one side and being connected to the first gas supply channel 245A and the second gas supply channel 245B through the first through hole 225A and the second through hole 225B, respectively, on the other side. Furthermore, in each of the first and the second branches 230A, 230B there may be fixtures to throttle the pressurized air. The first distribution branch 230A may comprise an electronically controlled first throttle valve 453A and the second distribution branch 230B may comprise an electronically controlled second throttle valve 453B. The first throttle valve 453A and the second throttle valve 453B may both be controlled by a control unit 455 which may allow for adjusting the flow through the first distribution branch 230A and the second distribution branch 230B. When one of the test sites 140A, 140B is not placed above the wafer 109 (compare FIG. 3B), e.g., the first test site 140A, and equivalent to this and the respective first branch 230A is free and loses pressurized gas, a respective first pressure sensor 455A in the first distribution branch 230A of the gas distribution unit 130 may sense the pressure decay. A connected control unit 455 may react and close the first throttle valve 453A. Since the same controlling of the gas flow may be achieved by a second pressure sensor 455B in the second distribution branch 230B of the gas distribution unit 130, a leakage for the pressurized gas may be avoided. However, in addition or as an alternative to this electronic control there may also be a first annular disc 451A placed in the first distribution branch 230A. A position of the first annular disc 451A may be adjusted by a first adjuster 452A (e.g. in the form of an adjusting screw) so that the first annular disc 451A may more or less throttle the gas flow through the first distribution branch 230A and thus limit a leakage, when the respective first branch 230A is free. The same may work with every test site 140 through which the gas flow is controlled and/or limited by a throttle valve 453B and/or an annular disc 451B, respectively.

However, as a further alternative or in addition, the branches 230A, 230B and/or the gas distribution channels 245A, 245B may initially be designed to have a specific flow resistance and thus may limit gas loss when the respective test site 140A, 140B is not located above the wafer 109. Overall, this may help to avoid the need to repeat tests of electronic components 209 at the test site 140A, 140B that is located above the wafer 109.

FIG. 4B and FIG. 4C show bar charts of an effect of limiting the flow through “open” test sites by applying a higher flow resistance towards the test sites. The term “open test site” refers to a test site which is not located above the wafer. Both charts are normalized to 100% of the respective value (flow rate and pressure), when all test sites are located above the wafer and are contacting to the respective DUTs.

FIG. 4B shows a bar chart of a decay of the flow rate for a single test site when all test sites are closed 491, when 2 of 8 test sites are open 492, when 4 of 8 test sites are open 493, when 6 of 8 test sites are open 494, and when 7 of 8 test sites are open 495. In this configuration, when the flow resistance is chosen or adjusted appropriately, the loss of the flow rate for the only closed (495) test site, or contacting test site is just below 90% even if 7 of 8 test sites are open 495.

FIG. 4C shows a bar chart of a decay of the pressure for a single test site when all test sites are closed 491, when 2 of 8 test sites are open 492, when 4 of 8 test sites are open 493, when 6 of 8 test sites are open 494, and when 7 of 8 test sites are open 495. In this configuration, the loss of the pressure for the only closed test site 495, or contacting test site is more than 90%, compared to the pressure when all test sites are located above the wafer 491.

FIG. 4B and FIG. 4C show an unexpected result that by adapting the flow resistance double testing may be avoided, while the pressure may have a value to allow for reducing arcing according to the Paschen's Law.

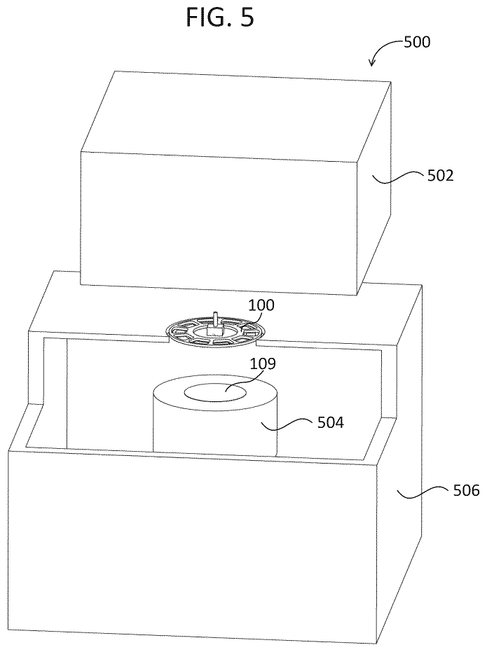

FIG. 5 shows a semiconductor test equipment 500 in a perspective view, according to an embodiment. In the illustrated embodiment, the semiconductor test equipment comprises a tester 502 and a prober 506. The prober 506, as illustrated, includes a chuck 504 configured to hold or house a wafer 109 during testing and a probe card 109 configured to contact the wafer 109 and control flow rates of a gas to test sites on the wafer 109 during testing, as described above.

In some embodiments, the tester 502 can provide electrical signals (e.g., electric current) to contact elements of the probe card 100. The electrical signals may be a test signal to test electronic components on the wafer 109. The tester may comprise one or more power sources configured to generate electrical signals and/or may pass electrical signals from external power sources. In some embodiments, the electrical signals may be configured to test high voltage semiconductor devices (e.g., the electrical signals may be 5-50V, 50-100V, 100-200V, 200-300V, 300 400V or a value in a range defined by any of these values or higher). The tester 502 may include a gas supply, such as the gas supply 230 illustrated in FIGS. 1A, 1B, 2A, 3A, 3B, and 4A, which can supply gas to gas supply channels of the probe card 100.

The tester 502 can include one or more control units, such as control unit 455. The control units may control various operations of the tester 502 and/or the prober 506. For example, the control units may control throttle valves of the probe card 100 (e.g., the first throttle valve 453A and the second throttle valve 453B). The control units may receive signals from the probe card 100. For example, the control units may receive signals from pressure sensors (e.g., the first pressure sensor 455A and the second pressure sensor 455B) from contact elements 142, and/or from other components of the probe card 100. The control units may receive signals from the prober 506. The control units may comprise one or more computer processors, such as physical central processing units (“CPUs”) or graphics processing units (“GPUs”), controllers, computer readable media (e.g., computer-readable storage devices, such as high density disks (“HDDs”), solid state drives (“SDDs”), flash drives, and/or other persistent non-transitory computer-readable media), and/or field-programmable gate arrays (“FPGA”). The computer readable media can store an operating system that provides computer program instructions for use by the control units in the general administration and operation of the tester 502. The computer-readable media can also include FPGA instructions for programming FPGAs.

The prober 506 can comprise the probe card 100, the chuck 504, inspection systems (e.g., optical inspection systems), positioning/handling systems, thermal control systems, interface systems, and/or any other suitable components or systems used in testing semiconductor devices. The chuck 504 may move the wafer 109 in a testing position and/or hold the wafer 109 in the testing position (e.g., a position in alignment with the probe card 100 such that the test sites of the probe card 100 align with respective electronic devices on the wafer 109). In some embodiments, the chuck 504 may control a temperature of the 109. For example, the chuck 504 can include heat sinks, liquid cooling, heaters, and/or other components suitable for raising or lowering a temperature of the wafer 109. A temperature control system may monitor and/or control the temperature of the chuck 504. A positioning/handling system may control a position of the wafer 109 and/or load/unload the wafer 109 from the chuck 504. An interface system may interface with other components of the semiconductor test equipment 500 (e.g., the tester 502) or components outside the test equipment 500. For example, the interface system may communicatively couple the prober 506 to the components, such that the prober 506 can receive signals (e.g., operational instructions) from the components and/or transmit signals to the components the components. An inspection system may include one or more sensors (e.g., optical sensors) that can sense a position of the wafer 109 and detect alignment errors.

While some examples of components included in the tester 502 and the prober 506 are described above, some of these components may be omitted from the tester 502 or the prober 506. Further, the tester 502 and/or the prober 506 may comprise other suitable components used in semiconductor testing. In various embodiments, the prober 506 may comprise some of, or all of, the components of the tester 502 and/or the tester 502 may comprise some of, or all of, the components of the prober 506 (e.g., one of the tester 502 or the prober 506 may be omitted and all components described above may be housed in the other of the tester 502 or the prober 506).

### Example Clauses

Clause 1. A probe head for parallel testing a plurality of electronic components (DUTs) on a wafer, in particular for parallel testing high voltage semiconductor components, comprises: an arrangement of a plurality of test sites, wherein each test site is adapted to test a different electronic component, a plurality of groups of contact elements, wherein each group of contact elements of the plurality of group of contact elements is assigned to a different one of the test sites and is adapted to contact to the respective electronic component, and wherein the probe head further comprises a plurality of gas supply channels, wherein each gas supply channel passes through a different test site of the plurality of test sites, and supplies separately pressurized gas to the assigned group of contact elements.

Clause 2. The probe head according to clause 1, wherein the supply of separately pressurized gas through the gas supply channels is adaptable by a mechanical adjustment of a flow resistance for the plurality of the gas supply channels.

Clause 3. The probe head according to clause 1 or 2, wherein a flow resistance for multiple of the gas supply channels is individually adjustable for each of the multiple gas supply channels.

Clause 4. The probe head according to any of the clauses 1 to 3, further comprising a plurality of electronically controllable throttle valves, wherein each one of the electronically controllable throttle valves is assigned to a different one of the gas supply channels, and wherein a flow resistance through each of the gas supply channels is electronically controlled by using the respective electronically controlled throttle valve; wherein in particular the flow resistance through each of the gas supply channels is increased as to switch off the flow completely by the assigned electronically controllable throttle valve.

Clause 5. The probe head according to any of the clauses 1 to 4, further comprising a gas supply, wherein the gas supply provides pressurized gas for each of the plurality of gas supply channels.

Clause 6. The probe head according to any of the clauses 1 to 5, wherein the separately pressurized gas is set to a pressure value preventing arcing between the contact elements within each group of contact elements, between two neighboring test sites, or between neighboring DUTs, according to Paschen's Law.

Clause 7. The probe head according to any of the clauses 2 to 6, wherein arcing between a first number of contact elements, adapted to contact to the wafer, is prevented according to Paschen Law, in that a gas pressure according to Paschen Law is fulfilled for the first number of contact elements, by in combination providing separately pressurized gas with a specific pressure value, and setting a specific value of the flow resistance through gas supply channels for a respective second number of contact elements being adapted to be free of contacting to the wafer.

Clause 8. The probe head according to any of the clauses 1 to 7, wherein the pressurized gas is pressurized air, and/or wherein the arrangement of the test sites provides a plurality of test gaps between the test sites in that the test sites are adapted to test every other or less than every other of the electronic components in one and/or the other direction of a main plane of the wafer.

Clause 9. The probe head according to any of the clauses 1 to 8, wherein the probe head further comprises a bottom surface, wherein the bottom surface comprises a main portion and a plurality of elevated portions, wherein each one of the elevated portions surrounds a different one of the groups of contact elements, and wherein the elevated portions are raised relative to the main portion.

Clause 10. A probe card comprising the probe head according to any of the clauses 1 to 9, and further comprising a board with a plurality of through holes, and a gas distribution unit, wherein the gas distribution unit separates the gas supply into different gas supply branches each entering a different one of the plurality of through holes and wherein each one of the plurality of through holes of the board being arranged between the gas distribution unit and the probe head feeds a different one of the gas supply channels with separately pressurized gas, respectively.

Clause 11. A method of parallel testing a plurality of electronic components on a wafer, in particular for parallel testing high voltage semiconductor components, comprises providing: an arrangement of a plurality of test sites, wherein each test site is adapted to test a different electronic component, a plurality of groups of contact elements, wherein each group of contact elements (of the plurality of group of contact elements) is assigned to a different one of the test sites and is adapted to contact to the respective electronic component, and wherein the probe head further comprises a plurality of gas supply channels, wherein each gas supply channel passes through a different test site 140 of the plurality of test sites and supplies separately pressurized gas to the assigned group of contact elements, wherein the method further comprises: parallel testing the plurality of electronic components by contacting the assigned group of contact elements to the plurality of electronic components on the wafer, and supplying separately pressurized gas to the assigned group of contact elements by the gas supply channels.

Clause 12. The method according to clause 11, wherein supplying of separately pressurized gas through the gas supply channels comprises: adapting a flow resistance for the plurality of the gas supply channels by a mechanical adjustment, and/or wherein the method further comprising: adjusting a flow resistance for multiple of the gas supply channels individually for each of the multiple gas supply channels and/or wherein the method further comprises providing a plurality of electronically controllable throttle valves, wherein each one of the electronically controllable throttle valves is assigned to a different one of the gas supply channels, and wherein the method further comprises: electronically controlling a flow resistance through each of the gas supply channels is by using the respective electronically controlled throttle valve, wherein the method in particular further comprises: increasing a flow resistance through each of the gas supply channels as to switch off the flow completely by the assigned electronically controllable throttle valve.

Clause 13. The method according to clause 11 or 12, further comprising providing a gas supply, and wherein the method further comprises: providing pressurized gas for each of the plurality of gas supply channels by the gas supply.

Clause 14. The method according to any of the clauses 11 to 13, wherein the method further comprises: setting the separately pressurized gas to a pressure value to prevent arcing between the contact elements within each group of contact elements, between two neighboring test sites, or between neighboring DUTs, according to Paschen's Law.

Clause 15. The method according to any of the clauses 11 to 14, wherein the method further comprises: preventing arcing between a first number of contact elements according to Paschen Law, the first number of contact elements contacting to the wafer, by providing a gas pressure according to Paschen Law for the first number of contact elements, in that in combination providing separately pressurized gas with a specific pressure value to the first number of contact elements, and setting a specific value of the flow resistance through gas supply channels for a respective second number of contact elements, the second number of contact elements not contacting to the wafer.

### Additional Examples I

1. A probe head for testing electronic components on a wafer, the probe head comprising:
   a plurality of test sites, each configured to test a different one of the electronic components;
   a plurality of groups of contact elements, each associated with a different test site of the plurality of test sites and configured to contact a respective electronic component to be tested in the different test site; and
   a plurality of gas supply channels, each passing through a respective test site of the plurality of test sites and configured to supply pressurized gas to a respective group of contact elements associated with the respective test site.
2. The probe head of Embodiment 1, wherein each gas supply channel of the plurality of gas supply channels comprises a mechanical adjustment configured to adjust a flow resistance of gas within the gas supply channel.
3. The probe head of Embodiment 2, wherein the mechanical adjustment of each gas supply channel individually adjusts the flow resistance of the gas.
4. The probe head of Embodiment 1, further comprising:
   a plurality of electronically controlled throttle valves, each configured to control a flow resistance of gas of a respective gas supply channel of the plurality of gas supply channels.
5. The probe head of Embodiment 4, wherein the electronically controlled throttle valves are configured to close off the gas to each respective gas supply channel of the plurality of gas supply channels.
6. The probe head of Embodiment 1, further comprising:
   a gas supply configured to provide pressurized gas to each of the plurality of gas supply channels.
7. The probe head of Embodiment 1, wherein the pressurized gas is set to a pressure value preventing arcing between two or more contact elements within each of group of contact elements of the plurality of groups of contact elements, between neighbouring test sites of the plurality of test sites, or between neighbouring devices under tests (DUTs), according to Paschen's Law.
8. The probe head of Embodiment 1, wherein the pressurized gas comprises pressurized air.
9. The probe head of Embodiment 1, wherein the plurality of test sites are configured to test every other ones of, or less than every other ones of, electronic component in a direction of a main plane of the wafer.
10. The probe head of Embodiment 9, further comprising one or more test gaps positioned between two of the plurality of test sites and above one or more electronic components on the wafer not tested by one of the plurality of test sites.
11. The probe head of Embodiment 1, further comprising:
   a bottom surface comprising a main portion and a plurality of elevated portions,
   wherein each one of the elevated portions surrounds a different one of the plurality of groups of contact element, and
   wherein the elevated portions protrude further from the bottom surface relative to the main portion.
12. The probe head of Embodiment 1, further comprising:
   a board comprising a plurality of through holes and a gas distribution unit, each one of the plurality of through holes being arrange between the gas distribution unit,
   wherein the gas distribution unit separates a gas supply into different gas supply branches, each entering a different one of the plurality of through holes, and
   wherein the gas distribution unit feeds the plurality of gas supply channels with the pressurized gas, respectively.

### Additional Examples II

1. A method for testing electronic components on a wafer, the method comprising: providing a probe head comprising:
   a plurality of test sites, each configured to test a different electronic component of a plurality of electronic components,
   a plurality of groups of contact elements, each associated with a different test site of the plurality of test sites and configured to contact a respective electronic component to be tested in the different test site, and
   a plurality of gas supply channels, each passing through a respective test site of the plurality of test sites and configured to supply pressurized gas to a respective group of contact elements associated with the respective test site;
testing the plurality of electronic components in parallel by contacting each group of contact elements to the plurality of electronic components; and
supplying the pressurized gas to the plurality of groups of contact elements by the plurality of gas supply channels.
2. The method of Embodiment 1, wherein supplying the pressurized gas to the plurality of groups of contact elements by the plurality of gas supply channels comprises:
   individually adapting a flow resistance of each of the plurality of gas supply channels by a mechanical adjustment.
3. The method of Embodiment 1, wherein each of the plurality of gas supply channels comprises an electronically controlled throttle valve, and wherein the method further comprises:
   controlling a flow resistance through each of the plurality of gas supply channels through the electronically controlled throttle valve of each of the plurality of gas supply channels.
4. The method of Embodiment 2, wherein the electronically controlled throttle valve of each of the plurality of gas supply channels is configured to close off the gas to the respective gas supply channel.
5. The method of Embodiment 1, wherein the probe head further comprises a gas supply, and wherein the method further comprises:
   supplying pressurized gas for each of the plurality of gas supply channels by the gas supply.
6. The method of Embodiment 1, further comprising:
   setting the pressurized gas to a pressure value to prevent arcing between two or more contact elements within each of group of contact elements of the plurality of groups of contact elements, between neighbouring test sites of the plurality of test sites, or between neighbouring devices under tests (DUTs), according to Paschen's Law.
7. The method of Embodiment 1, wherein supplying the pressurized gas to the plurality of groups of contact elements by the gas supply channels comprises:
   providing pressurized gas with a specific pressure value to a first number of contact elements, wherein the first number of contact elements contact the wafer, and wherein the specific pressure value is configured to prevent arcing between the first number of contact elements according to Paschen Law; and
   setting a specific value of flow resistance through gas supply channels for a second number of contact elements, wherein the second number of contact elements do not contact the wafer.
8. The method of Embodiment 1, wherein the plurality of test sites are configured to test every other ones, or less than every other ones of, of the electronic components in a direction of a main plane of a wafer.

### Additional Examples III

1. A semiconductor test equipment for wafer-level testing of electronic components, the semiconductor test equipment comprising:
   a probe head comprising a plurality of test sites configured to simultaneously contact a plurality of electronic components formed on a semiconductor wafer;
   a plurality of groups of contact elements, each group associated with a different test site of the test sites and configured to contact a respective electronic component to be tested; and
   a gas distribution unit configured to independently control flow rates of a gas to the different test sites during testing using independent gas supply channels.
2. The semiconductor test equipment of Embodiment 1, wherein each gas supply channel comprises a mechanical adjustment configured to adjust a flow resistance of gas within the gas supply channel.
3. The semiconductor test equipment of Embodiment 2, wherein the mechanical adjustment comprises a throttle valve.
4. The semiconductor test equipment of Embodiment 2, further comprising a controller configured to individually adjust different ones of the mechanical adjustments.
5. The semiconductor test equipment of Embodiment 1, further comprising a gas supply configured to provide pressurized gas to the gas distribution unit.
6. The semiconductor test equipment of Embodiment 5, wherein the pressurized gas comprises pressurized air.
7. The semiconductor test equipment of Embodiment 1, wherein the plurality of test sites are configured to contact every other ones of, or less than every other ones of, the electronic components in a direction of a main plane of the semiconductor wafer.
8. The semiconductor test equipment of Embodiment 1, wherein the probe head further comprises one or more test gaps positioned between two of the plurality of test sites and above one or more electronic components formed on the wafer not contacted by one of the plurality of test sites.
9. The semiconductor test equipment of Embodiment 1, wherein the probe head further comprises:
   a bottom surface comprising a main portion and a plurality of elevated portions,
   wherein each one of the elevated portions surrounds a different one of the plurality of groups of contact element, and
   wherein the elevated portions protrude further from the bottom surface relative to the main portion.

Unless the context clearly requires otherwise, throughout the description and the embodiments, the words “comprise,” “comprising,” “include,” “including,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list. All numerical values provided herein are intended to include similar values within a measurement error.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states.

The teachings provided herein can be applied to other systems, not necessarily the systems described above. The elements and acts of the various embodiments described above can be combined to provide further embodiments. The acts of the methods discussed herein can be performed in any order as appropriate. Moreover, the acts of the methods discussed herein can be performed serially or in parallel, as appropriate.

While certain embodiments have been described, these embodiments have been presented by way of example only, and are not intended to limit the scope of the disclosure. Indeed, the novel methods and systems described herein may be embodied in a variety of other forms. Furthermore, various omissions, substitutions and changes in the form of the methods and systems described herein may be made without departing from the spirit of the disclosure. For example, while the disclosed embodiments are presented in given arrangements, alternative embodiments may perform similar functionalities with different components and/or circuit topologies, and some elements may be deleted, moved, added, subdivided, combined, and/or modified. Each of these elements may be implemented in a variety of different ways as suitable. Any suitable combination of the elements and acts of the various embodiments described above can be combined to provide further embodiments. The accompanying claims and their equivalents are intended to cover such forms or modifications as would fall within the scope and spirit of the disclosure. Accordingly, the scope of the present inventions is defined by reference to the claims.

What is claimed is:

1. A probe head for testing electronic components on a wafer, the probe head comprising:
a plurality of test sites, each configured to test a different one of the electronic components;
a plurality of groups of contact elements, each associated with a different test site of the plurality of test sites and configured to contact a respective electronic component to be tested in the different test site; and
a plurality of gas supply channels, each passing through a respective test site of the plurality of test sites and configured to supply pressurized gas to a respective group of contact elements associated with the respective test site.

2. The probe head of claim 1, wherein each gas supply channel of the plurality of gas supply channels comprises a mechanical adjustment configured to adjust a flow resistance of gas within the gas supply channel.

3. The probe head of claim 2, wherein the mechanical adjustment of each gas supply channel individually adjusts the flow resistance of the gas.

4. The probe head of claim 1, further comprising:
a plurality of electronically controlled throttle valves, each configured to control a flow resistance of gas of a respective gas supply channel of the plurality of gas supply channels.

5. The probe head of claim 4, wherein the electronically controlled throttle valves are configured to close off the gas to each respective gas supply channel of the plurality of gas supply channels.

6. The probe head of claim 1, further comprising:
a gas supply configured to provide pressurized gas to each of the plurality of gas supply channels.

7. The probe head of claim 1, wherein the pressurized gas is set to a pressure value preventing arcing between two or more contact elements within each of group of contact elements of the plurality of groups of contact elements, between neighbouring test sites of the plurality of test sites, or between neighbouring devices under tests (DUTs), according to Paschen's Law.

8. The probe head of claim 1, wherein the pressurized gas comprises pressurized air.

9. The probe head of claim 1, wherein the plurality of test sites are configured to test every other ones of, or less than every other ones of, electronic component in a direction of a main plane of the wafer.

10. The probe head of claim 9, further comprising one or more test gaps positioned between two of the plurality of test sites and above one or more electronic components on the wafer not tested by one of the plurality of test sites.

11. The probe head of claim 1, further comprising:
a bottom surface comprising a main portion and a plurality of elevated portions,
wherein each one of the elevated portions surrounds a different one of the plurality of groups of contact element, and
wherein the elevated portions protrude further from the bottom surface relative to the main portion.

12. The probe head of claim 1, further comprising:
a board comprising a plurality of through holes and a gas distribution unit, each one of the plurality of through holes being arrange between the gas distribution unit,
wherein the gas distribution unit separates a gas supply into different gas supply branches, each entering a different one of the plurality of through holes, and
wherein the gas distribution unit feeds the plurality of gas supply channels with the pressurized gas, respectively.

13. A semiconductor test equipment for wafer-level testing of electronic components, the semiconductor test equipment comprising:
a probe head comprising a plurality of test sites configured to simultaneously contact a plurality of electronic components formed on a semiconductor wafer;
a plurality of groups of contact elements, each group associated with a different test site of the test sites and configured to contact a respective electronic component to be tested; and
a gas distribution unit configured to independently control flow rates of a gas to the different test sites during testing using independent gas supply channels.

14. The semiconductor test equipment of claim 13, wherein each gas supply channel comprises a mechanical adjustment configured to adjust a flow resistance of gas within the gas supply channel.

15. The semiconductor test equipment of claim 14, wherein the mechanical adjustment comprises a throttle valve.

16. The semiconductor test equipment of claim 14, further comprising a controller configured to individually adjust different ones of the mechanical adjustments.

17. The semiconductor test equipment of claim 13, further comprising a gas supply configured to provide pressurized gas to the gas distribution unit.

18. The semiconductor test equipment of claim 13, wherein the plurality of test sites are configured to contact every other ones of, or less than every other ones of, the electronic components in a direction of a main plane of the semiconductor wafer.

19. The semiconductor test equipment of claim 13, wherein the probe head further comprises one or more test gaps positioned between two of the plurality of test sites and above one or more electronic components formed on the wafer not contacted by one of the plurality of test sites.

20. The semiconductor test equipment of claim 13, wherein the probe head further comprises:
a bottom surface comprising a main portion and a plurality of elevated portions,
wherein each one of the elevated portions surrounds a different one of the plurality of groups of contact element, and
wherein the elevated portions protrude further from the bottom surface relative to the main portion.
